(19) United States
(12) Patent Application Publication
(10) Pub. No.: US 2019/0320535 A1
(43) Pub. Date: Oct. 17, 2019

(54) PROCESS FOR 3D PRINTING AN ARTICLE INCORPORATING A CONDUCTIVE CIRCUIT COMMUNICATING WITH A SEPARATELY INSTALLABLE ELECTRICAL COMPONENT AND AN ARTICLE PRODUCED THEREBY

(71) Applicants: Jeff Demmers, Lake Orion, MI (US); Charles Atwood, Chesterfield, MI (US)

(72) Inventors: Jeff Demmers, Lake Orion, MI (US); Charles Atwood, Chesterfield, MI (US)

(21) Appl. No.: 16/385,268

(22) Filed: Apr. 16, 2019

Related U.S. Application Data
(60) Provisional application No. 62/658,166, filed on Apr. 16, 2018.

(51) Int. Cl. H05K 3/10; B29C 64/165; B29C 64/393; H05K 3/00

(52) U.S. Cl. CPC H05K 3/108; B29C 64/165; B33Y 10/00; H05K 3/0014; B29C 64/393

(57) ABSTRACT

An improved process combining a first insulating filament (ABS/TPE/TPG) material with a second conductive filament (Graphite PLA) material during a 3D printing operation in order to produce a part (not limited to head/tail lamp bezels, hearing aids and cardio monitors incorporating circuitry for providing power, lighting and enhanced heat removal. The process includes the step of modifying the additive process programming at determined intermediate points to allow for installation of non-3D printable electrical components (resistors, diodes, etc.), such as in a lay-in press-fit technique in order to communicate with the conductive pathways incorporated in the printed circuit board article.

### CROSS REFERENCE TO RELATED APPLICATIONS

The present application claims priority of U.S. Ser. No. 62/658,166 filed Apr. 16, 2018.

### FIELD OF THE INVENTION

The present invention generally relates to the use of conductive materials, such as graphene filaments, in the creation of components integrating electrical circuitry functionality, and further such as is produced utilizing three dimensional (3D) or like additive printing capabilities. More specifically, the present invention discloses an improved process for creating a 3D article including the lay-in and/or press fit techniques for installing circuit components during an intermediate stage of the additive process, as well as providing for improved heat sinking applications for creating an improved 3D printed component which incorporates basic circuit functionality.

### BACKGROUND OF THE INVENTION

The prior art is documented with various systems, applications and techniques for the creation of articles utilizing 3D printing and other related additive processes. Three dimensional (3D) or additive manufacturing (AM) printing is further generally known as a fabrication technique used for building three-dimensional structures and solid objects. A typical process utilizes the adding of layers of material, one atop each other, and in contrast to subtractive fabrication methods such as sculpture where you need to remove stone in order to from the final object, and in order to create a solid object.

By operation, the 3D printer deposits printing material on a print bed (also called build platform) following the design of a 3D file, often a STL or OBJ format file which is provided in a series of consecutive commands fed to a three dimensional numerically controlled assembly upon which the print head is supported. Alternatively, the print head can be stationary mounted or be limited to movement along a pair of horizontal axis, with the numerically controlling structure both supporting and manipulating a build platform upon which the 3D printed material is applied, such being moved relative to the nozzle application location of the print head including being moved downwardly in a third vertical dimension to account for previously executed additive material deposition steps.

The material, typically melted plastic for FFF and FDM 3D printers, is deposited layer by layer in response to receipt and execution of each consecutive command from the operating code. As is customary with existing additive processes, each layer is thin and quickly solidifies, thus forming three-dimensional objects. As is further generally known, most desktop 3D printers use plastic filament spools as consumables.

Proceeding from the above explanation, many types of 3D printing technologies are currently available commercially or at the early development stage. Each of these additive manufacturing techniques requires a specific type of 3D printing material: from plastic filaments (PLA, ABS . . . ) to photosensitive resin to powdered material (metals, plastics etc). These 3D printing technologies have various advantages and can be used in specific applications and use cases.

As is further known, the main categories of 3D printing include each of extrusion (EFF and FDM) additive processes in which a plastic filament is melted and deposited on the build platform located underneath the print head. Extrusion additive printing (also known as FDM for Fused Deposition Modeling or FFF for Fused Filament Fabrication) is the most common 3D printing technique, and is used by the majority of desktop 3D printers. Extrusion/FDM processes use a plastic filament (PLA or ABS) as the printing material. The filament is heated and melted in the printing head (extruder) of the 3D printer.

As described previously, one aspect of the numerically controllable print head contemplates it moving along two horizontal axes (X and Y axis), while the tray supporting the build platform object moves vertically on the Z axis. The 3D printer deposits the melted filament by layer, each layer on top of the others, to build the object in 3D. When one layer is complete, the tray holding the object lowers very slightly and the extrusion process resumes, depositing a new layer of melted filament on top of the previous one. Deposited layers are fused together as the melted plastic quickly solidifies to form a solid three-dimensional object. When one layer is complete, the tray holding the object lowers very slightly and the layering process resumes, depositing a new layer on melted filament on top of the previous one. In this fashion, deposited layers are fused together as the melted plastic quickly solidifies to form a solid three-dimensional object.

Having provided a basic description of existing 3D/additive material forming processes, from Graphene 3D Labs is disclosed a Conductive Graphene Filament (Black Magic 3D) which is utilized in 3D printing for creating circuitry, sensors and the like. The conductive graphene filament is further explained as applying to 3D print circuitry, including capacitive touch sensors and for EMI and RF shielding. Circuit applications within a 3D print process further include creation of computer interfaces and Arduino boards, as well as creating power up items such a LED's and wearable electronics, capacitive touch sensors, controllers, digital keyboards, trackpads, etc.

US 2016/0326386, to Toyserkani, teaches a method and system for 3D printing of flexible graphene electronic devices and deposition of graphene on non-planar surfaces. Rather than a filament, the graphene is applied as a powder and a pair of solvents.

US 2017/0144373, to Erikson et al., teaches a molten filament containing a conductive material extruded from a print head of a 3D printer.

US 2017/0209622, to Shah et al., teaches a graphene based ink composition for 3D printing applications.

Finally, US 2017/0284876, to Moorlag et al., teaches a 3D printed conductive composition including each of a body and a 3D printable conductive composite segment in mechanical communication with the body.

### SUMMARY OF THE INVENTION

The present invention discloses an improved 3D printing process which combines each of an insulating (ABS/TPE/TPG) material with a conductive (Graphite PLA) for printing a highly conductive graphene filament (such as is by itself known in general use in 3D printing applications), and which utilizes improved techniques for producing an article having integrated circuit board functionality for providing power, lighting and enhanced heat removal (sinking) capabilities. In this fashion, the present invention makes possible the creation of various parts, including head/tail lamp bezels, hearing aids and cardio monitors, which are beyond the capabilities of existing 3D printing or additive material (AM) technologies.

The present invention, including the protocols and functionality incorporated into the 3D additive process, additionally provides the ability to pause the additive process at a determined intermediate position in order to insert suitable electrical components (resistors, diodes, etc.) in a lay-in press-fit technique for the purpose of integrating such componentry at an intermediate stage of the 3D or additive forming process and prior to completing the finished article.

### BRIEF DESCRIPTION OF THE DRAWINGS

Reference will now be made to the attached illustrations, when read in combination with the following detailed description, wherein like reference numerals refer to like parts throughout the several views, and in which:

FIGS. 1-3 present a series of perspective, side and top views of a 3D printed component incorporating a first base material in combination with a second conductive filament material, as well as the use of electrical components applied in an intermediate press fit fashion according to one non-limiting embodiment of the present invention;

FIG. 4 is an illustration of a 3D printing machine such as which is utilized with the formation of the component with conductive pathways according to the present invention;

FIGS. 5-6 are top and bottom perspective views of a 3D printed component similar to that shown in FIGS. 1-3 and utilizing the 3D printing machine of FIG. 4; and

FIG. 7 is an illustration of a further example of a 3D additive printed article produced according to the present invention.

### DETAILED DESCRIPTION OF THE PREFERRED EMBODIMENTS

As previously described the present invention discloses an improved 3D printing process which combines each of an insulating (ABS/TPE/TPG) material with a conductive (Graphite PLA) for printing a highly conductive graphene filament (such as is by itself known in general use in 3D printing applications). In this fashion, the present invention utilizes improved techniques for producing an article having integrated circuit board functionality for providing power, lighting and enhanced heat removal (sinking) capabilities. In this fashion, the present invention makes possible the creation of various parts, including head/tail lamp bezels, hearing aids and cardio monitors, which are beyond the capabilities of existing 3D printing or additive material (AM) technologies.

The present invention additionally discloses and functionality incorporated into the 3D additive process, and additionally provides the ability to pause the additive process at a determined intermediate position in order to insert suitable electrical components (resistors, diodes, etc.) in a lay-in press-fit technique for the purpose of integrating such componentry at an intermediate stage of the 3D or additive forming process and prior to completing the finished article.

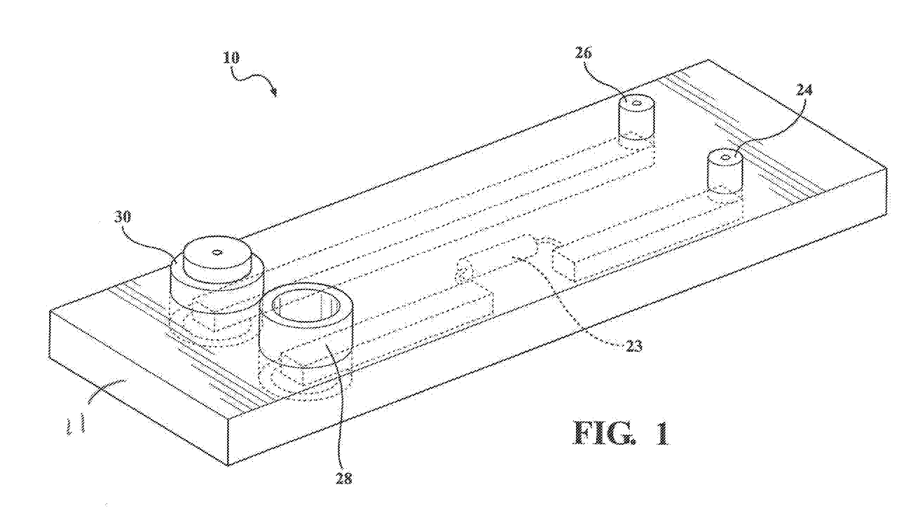

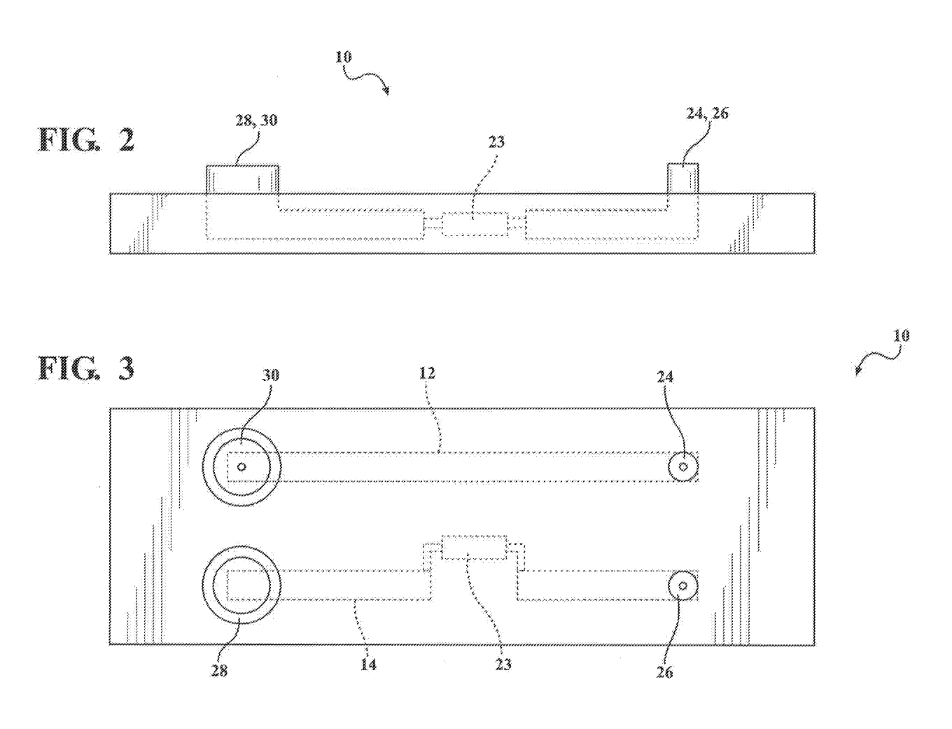

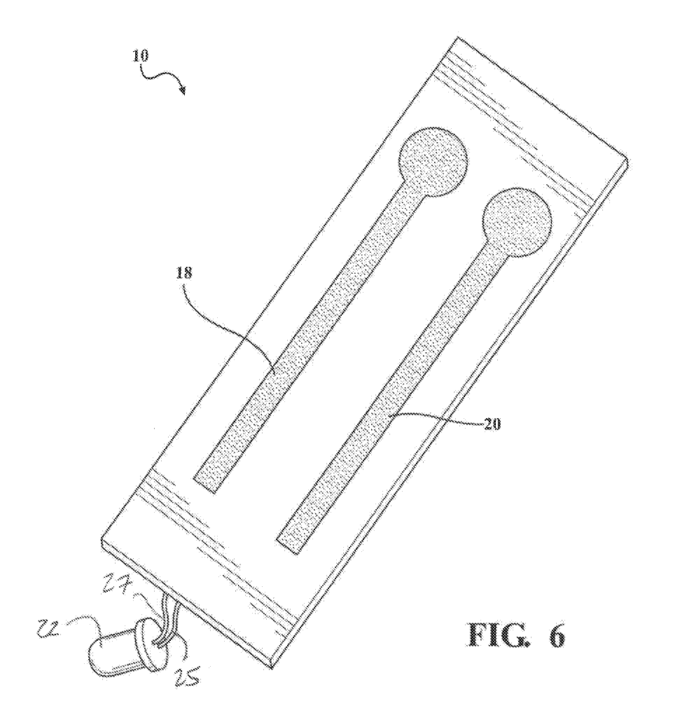

With reference to FIGS. 1-3, presented are a series of perspective, side and top views of a 3D printed and circuit supporting component, generally at 10, and which incorporates a first base insulating material (generally referenced at 11), again including (ABS/TPE/TPG), in combination with a second conductive material (referencing integrated pathways 12, 14, 16, 18 and 20 in FIGS. 5-6, which are not limited to a graphene fed filament and such as is sold under the name BlackMagic3D by Graphene Lab Inc. Given further that graphene is mechanically strong and a good conductor of electricity and heat, it is useful in 3D printing applications in which basic circuitry functions are desired to be integrated into the insulated and printed material matrix 11 of the created article, and as further configured according to the present description.

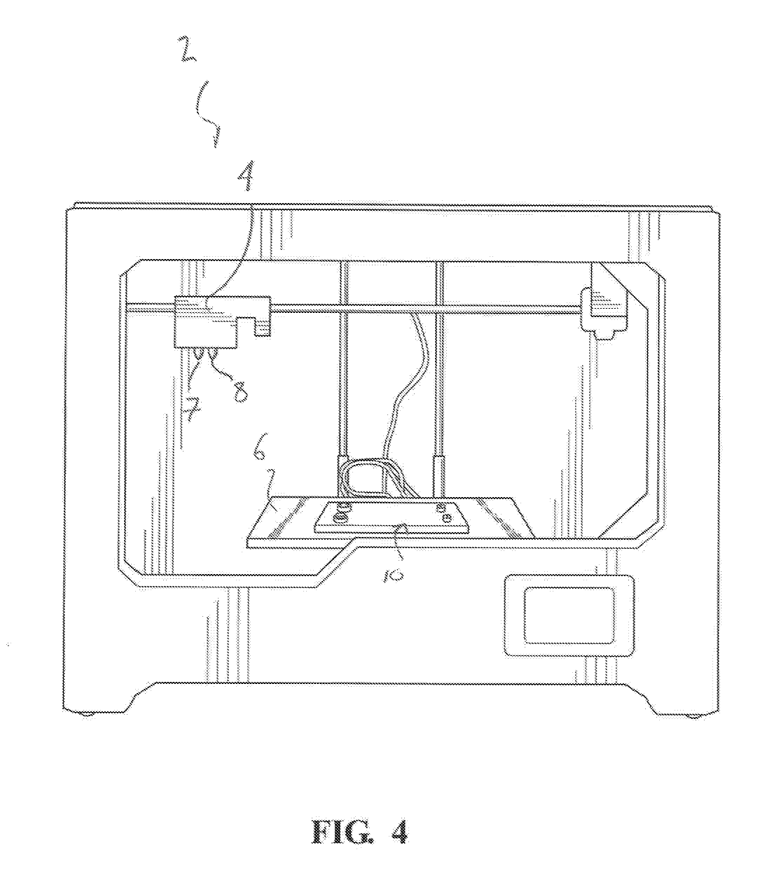

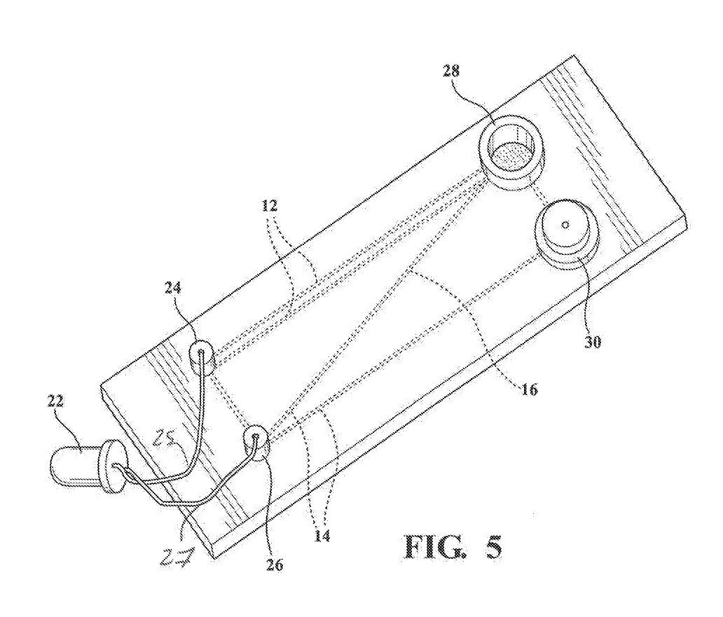

FIGS. 5-6 further depict top and bottom perspective views of a 3D printed component, similar to that depicted in FIGS. 1-3, which is produced utilizing the 3D printing machine of FIG. 4 (generally at 2) and which further better illustrates conductive circuit pathways or traces, these shown at 12, 14, 16, et seq. in FIG. 5, with additional 3D printed pathways further at 18 and 20 in the rotated view of FIG. 6. As previously described, the simultaneous print feed addition of the conductive filament, along with the insulating base or stock material, is integrated into the operating program for creating the desired conductive enabled component.

Additional electrical components are provided and are shown at 22, 23, 24, 26, 28 and 30 arranged at locations throughout the circuit integrated article depicted in each of FIGS. 1-3 and 5-6. These are not limited to any specific type of electrically conducting component (such as which cannot typically be 3D printed) and can include but are not limited to any of diodes (such as at 23), resistors, conductive posts (at 24, 26, 28 and 30), capacitors, and L.E.D. components (at 22) and connected by a pair of wires 25 and 27 to the posts 24 and 26 in FIG. 5. The electrically conducting components are understood to be provided as separate stock components and which, as will be subsequently described, are intended to be integrated (such as through press fit installation) into the additive printed/developing conductive graphene circuit pathways 3D printed within the article body.

In operation, and upon the print head 4 in FIG. 4 executing a given number of passes as determined by the operating program associated with the additive (AM) or 3D printer head 4 of the 3D printer 2 depicted in the example of FIG. 4, the printed article 2 is printed to a thickness or depth typically partial to that shown in the completed perspective of FIG. 1 in a manner supported upon the platen or support surface, at 6. At this point, the 3D additive material including both the insulated component (issued through selected injection nozzle 7 defined in the printer head 4) and the conductive graphene component (further issued through proximally located injection nozzle 8), are each in a typically softened or semi-set state such that desired components may be press fit into the setting/solidifying material at a paused and intermediate process step of the part creation operation.

Following the integration/embedding of the conventional electrical component into the semi-additive formed part, the 3D printing process is resumed for the remaining steps/passes as dictated by the operating program and in order to complete the part in such a fashion as to integrate the conventional electrical component into the matrix of the 3D part. In this manner, the various press fit components can be either partially or (as shown by diode 23) encapsulated within the additive material and in such a fashion that they interact in the desired fashion with the conductive traces (see again 12, 14, 16, 18 and 20) established by the conductive additive (graphene applied) material combined with the insulated material matrix, and further in order to provide the completed article with the desired structural, electrical and heat dissipating/sinking characteristics.

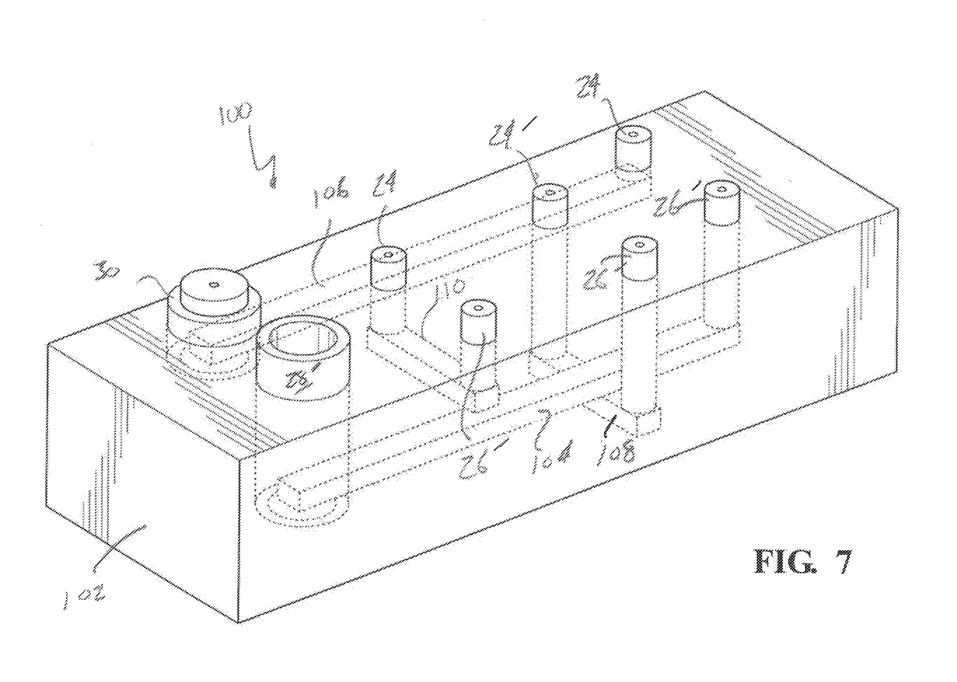

Finally, FIG. 7 is an illustration, generally at 100, of a further example of a 3D additive printed article produced according to the present invention. In comparison to that shown at 10 in FIG. 1, the additive printed article 100 can exhibited any variable thickness (such as depicted at 102) and which is created through the successive additive printing of the desired insulating material. Concurrently, the conductive graphene or other print-applied material is likewise issued according to the desired numerically controlled operating program through the second multi-directional adjustable feed nozzle and which is further shown as axial elongated conductive pathways 104 and 106, in combination with lateral or crosswise and depth offset pathways 108 and 110.

The operator attached components are again depicted at 24, 24′, 26′ and 30 similar to those shown in the embodiment of FIG. 1, with a further extended modified component 28′ modified from that shown in FIG. 1 at 28 also being provided for communicating a selected axial conductive trace or pathway (again 104) with a surface exposed location of the component 28′. Without limitation, the operational protocol for the additive creation of the circuit supporting 3D printed article contemplates the separate components being installed either during a single interrupted point during the program (such as near the end in which the components are at least partially exposed as shown) or, alternatively, can be installed at multiple points as the article is progressively being created (this further shown by selected components 24′, 26′ and 28′ which are installed at earlier interrupted locations to allow for succeeding additive passes of insulating material 102 to flow over and build up around the lengthened components (as well as to embed other components such as the diode 23 depicted in FIG. 1).

Without limitation, the material additive process employed can be utilized with a suitable 3D printing machine 2 and variable collection of installable electrical (stock) components, this in order to quickly create custom shaped circuit pathway enabled articles which can include unique shapes and functionality. By virtue of the present process, the operator is provided with the ability to more efficiently produce a considerable number of 3D printed articles with less input than that required in the installation and soldering assembly of typical printed circuit board technology.

The time and effort savings realized include the operator's attention being limited to one or more brief install points occurring during an interrupted portion of the 3D printing protocol (such as which can be associated with the 3D printer issuing a suitable alarm for notifying the operator to press-fit install the desired components at the intermediate interrupted position). Given that the press fit attachment of the desired electrical components according to the present invention can be accomplished very quickly (and again as opposed to the alternative of time intensive printed circuit board production and soldering), this provides a single operator the ability to stagger an operational program cycle for each of a plurality of 3D printing machines so that adequate attention can be paid to each machine during its interrupted interval and as the printed article develops (or grows) until completed by the final pass. The present invention also contemplates the press fit installation of the separate electrical components can be automated within a redesign of the 3D printing machine architecture, such as which can also be directed by the supporting controller operating program and in order to time and direct the placement of such components as an alternative to the operator installing in a manual press fit fashion.

Having described our invention, other and additional preferred embodiments will become apparent to those skilled in the art to which it pertains, and without deviating from the scope of the appended claims. The detailed description and drawings are further understood to be supportive of the disclosure, the scope of which being defined by the claims. While some of the best modes and other embodiments for carrying out the claimed teachings have been described in detail, various alternative designs and embodiments exist for practicing the disclosure defined in the appended claims.

We claim:

1. A 3D printing process for creating an article having conductive pathways, comprising the steps of:
providing a three dimensional printing machine having each of a support platen located within a printing enclosure and a multi-directional printing head actuated by a separate controller;
communicating a plurality of successive commands of a software program to the controller to cause timed and directed actuations of the printing head in response to each of the commands, the printing head being caused to issue each of a first insulating base material and a second conductive material integrated within the base material;
interrupting operation of the printing head at least once prior to completion of the programmed commands;
installing at least one electrical component into the base material so that the component is also in communication with at least one pathway associated with the conductive material; and
resuming operation of the printing head and, following completion of all of the commands, removing the article from the printing enclosure.

2. The 3D printing process as described in claim 1, further comprising the step of configuring the printing head with each of a first nozzle for issuing said insulating material and a second nozzle for issuing said conductive material.

3. The 3D printing process as described in claim 2, the step of the software program issuing commands to the printer head further comprising the step of issuing subset commands to each of the first and second nozzles.

4. The 3D printing process as described in claim 1, the step of issuing a first insulating base material further comprising any of an ABS, TPE or TPG material.

5. The 3D printing process as described in claim 1, the step of issuing a second conductive material further comprising a graphite material.

6. The 3D printing process as described in claim 1, further comprising the step of providing at least one of power, lighting and enhanced heat removal (sinking) capabilities to the printed article.

7. A 3D printing article having conductive pathways, comprising:
a first insulating base material and a second conductive material integrated within the base material; and
at least one electrical component press fit into the base material during at least one pause in the additive forming of the article, said component also being in communication with at least one pathway associated with said conductive material prior to completion of additive printing of at least an additional volume of said insulating material.

8. The article of claim 7, the article including at least one of a headlamp or tail lamp bezel, a hearing aid and a cardio monitor.
